(19) United States
(12) Patent Application Publication
(10) Pub. No.: US 2006/0197199 A1
(43) Pub. Date: Sep. 7, 2006

(54) Leadframe, coining tool, and method

(76) Inventor: Bernhard Peter Lange, Garland, TX (US)

Correspondence Address: TEXAS INSTRUMENTS INCORPORATED, P O BOX 655474, M/S 3999, DALLAS, TX, 75265, US

(21) Appl. No.: 11/073,173

(22) Filed: Mar. 5, 2005

(51) Int. Cl. H01L 21/50; H01L 23/495

(52) U.S. Cl. 257/673; 438/123; 257/E23.036

(57) ABSTRACT

Semiconductor leadframes are provided with selected coined and uncoined areas. The coined areas are arranged to coincide with connection sites for electrical couplings, and the uncoined areas are arranged to provide a secure mechanical bond between leadframe and die attach material or leadframe and encapsulant. Methods are disclosed for forming a leadframe including steps for providing a leadframe that has a die pad and leadfingers extending from the die pad, and coining a selected portion of the die pad using a high pressure coining tool configured to make contact with the selected portion of the die pad and to avoid contact with the remainder of the die pad. A leadframe coining tool is also disclosed for use in a high pressure press. The coining tool includes one or more contact area for coining a portion of the die pad, and at least one non-contact area, whereby a die pad of an aligned leadframe may be partially coined.

### TECHNICAL FIELD

The invention relates to the manufacture of integrated circuitry. More particularly, the invention relates to leadframes, tools, and methods useful for assembling integrated circuits, and to planar leadframes having a die pad and leadfinger configuration.

### BACKGROUND OF THE INVENTION

Modern chips are often manufactured without leads and are later fitted to a leadframe structure and encapsulated in plastic packages in order to protect the IC and to provide connective leads for coupling the terminals of the IC to the outside world, such as a PC board. Problems are encountered with packaged IC devices used in the arts both in the manufacturing stages and in testing and use. Among the problems, some of the most common and debilitating are the separation of layers of devices, and open or short circuits caused by separation of materials or the ingress of moisture between separated materials.

In order to facilitate the formation of wirebonds coupling IC device terminals to leadframes, the leadframes are often flattened by the application of a high pressure press in a process generally called “coining”. The coined area typically includes the die attach area of the leadframe and the inner ends of the lead fingers. While the coined leadframe surface provides a smooth area improved for the purposes of wirebonding, the adhesion of die attach material or encapsulant material can be impeded by the smoothness of the coined surface.

Improved leadframes, leadframe coining tools, and methods for improving leadframe to IC bonding would be useful and advantageous in the arts. Such improved bonds would provide increased resistance to shearing and separating forces, inhibit the propagation of cracks, and block the ingress of foreign materials.

### SUMMARY OF THE INVENTION

In carrying out the principles of the present invention, in accordance with preferred embodiments thereof, leadframes are provided with selected coined and uncoined areas. The coined areas are arranged to coincide with connection sites for electrical couplings, and the uncoined areas are arranged to provide a secure mechanical bond between leadframe and die attach material or leadframe and encapsulant.

According to an aspect of the invention, a method of forming a leadframe includes a step for providing a leadframe that has a die pad, and leadfingers extending from the die pad. The method also includes coining a selected portion of the die pad using a high pressure coining tool configured to make contact with the selected portion of the die pad and to avoid contact with the remainder of the die pad.

According to another aspect of the invention, in an example of a preferred embodiment, a leadframe has a coined portion providing a surface for bonding to an electrical contact, and an uncoined portion providing an attachment surface for bonding to a chip.

According to another aspect of the invention, a leadframe embodiment is provided in which the coined portion includes the periphery of a die pad.

According to yet another aspect of the invention, a leadframe embodiment is provided with at least one coined leadframe portion on an internal area of a die pad surface.

According to another aspect of the invention, in a preferred embodiment thereof, a leadframe coining tool for use in a high pressure press includes at least one die portion for alignment with a leadframe having a die pad. The die portion further includes one or more contact area for coining a portion of the die pad, and at least one non-contact area, whereby a die pad of an aligned leadframe may be partially coined by the high pressure press.

The invention has advantages including but not limited to improved bonding material adhesion and improved encapsulant adhesion due to enhanced leadframe bonding surfaces. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1A is a planar view of an example of a portion of a metallic leadframe for use with the invention;

FIG. 1B is a planar view illustrating an example of providing the leadframe of FIG. 1A with a selected coined area in accordance with a preferred embodiment of the invention;

FIG. 1C is a planar view illustrating an example of an IC affixed to the leadframe of FIG. 1B in accordance with a preferred embodiment of the invention;

FIG. 2 is a planar view of an example of an alternative embodiment of a leadframe according to the invention;

FIG. 3 is a planar view of another example of an alternative embodiment of a leadframe according to the invention;

FIG. 4 is a planar view of an example of an alternative embodiment of a leadframe coining die according to the invention;

FIG. 5 is a planar view of an example of an alternative embodiment of a leadframe coining die according to the invention;

FIG. 6 is a planar view of an example of another alternative embodiment of a leadframe coining die according to the invention;

FIG. 7 is a planar view of another example of an alternative embodiment of a leadframe coining die according to the invention;

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DETAILED DESCRIPTION OF PREFERRED EMBODIMENTS

In general, the invention provides improved leadframes, tools, and methods for their manufacture. The leadframe is partially coined for wirebond purposes and remains partially uncoined to facilitate device-to-leadframe attachment. Examples of preferred embodiments of the inventions provide secure wirebonds between electrical contacts of a chip and leadframe, as well as secure mechanical bonds between non-electrical-contact portions of the chip and leadframe.

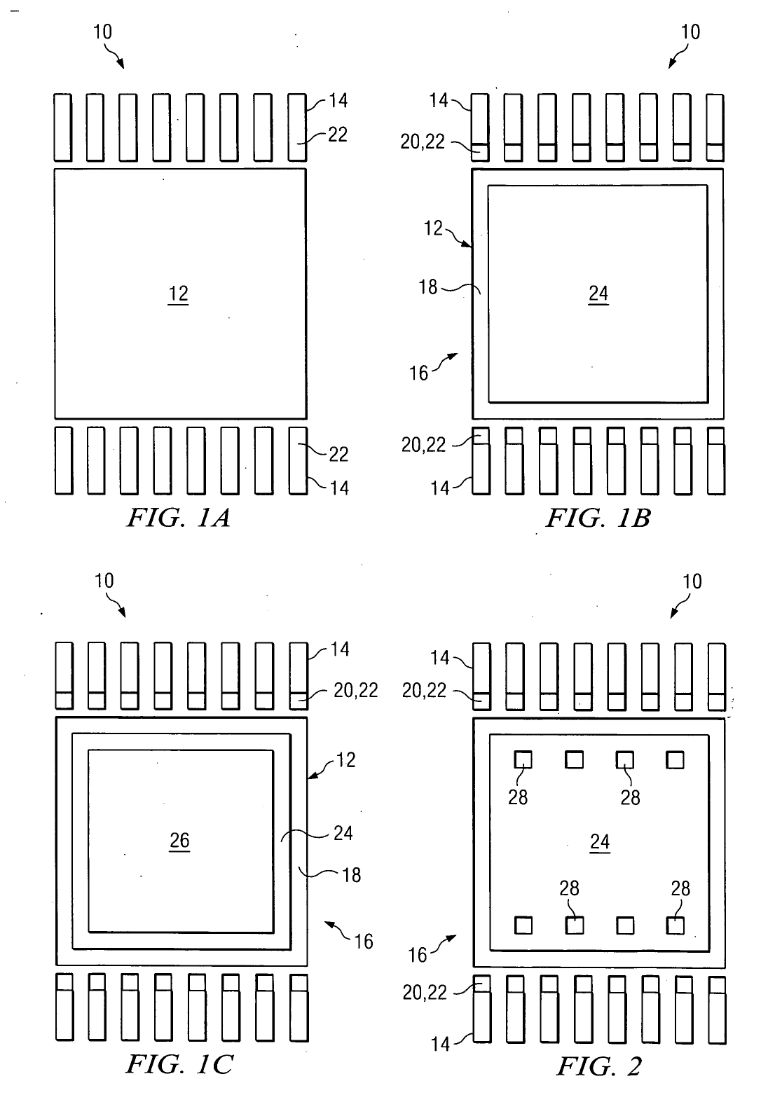

Referring primarily to FIGS. 1A through 1C, an example of a leadframe and method according to the invention is shown. The leadframe 10 has a die pad area 12 and leadfingers 14 familiar in the arts. FIG. 1B shows an example of a leadframe 10 as in FIG. 1A following a coining step in which the leadframe 10 is coined to form selected coined areas 16. The coined areas 16 in this example include a portion 18 of the die pad 12 and a portion 20 of each of the lead fingers 14, in this case, the inner ends 22. In this example, the coined portion 18 of the die pad includes the entire periphery of the die pad. An uncoined portion 24 of the die pad 12 has been retained to facilitate adhesion of epoxy or other suitable material known in the arts for attaching an IC 26 to the die pad 12 as depicted in FIG. 1C.

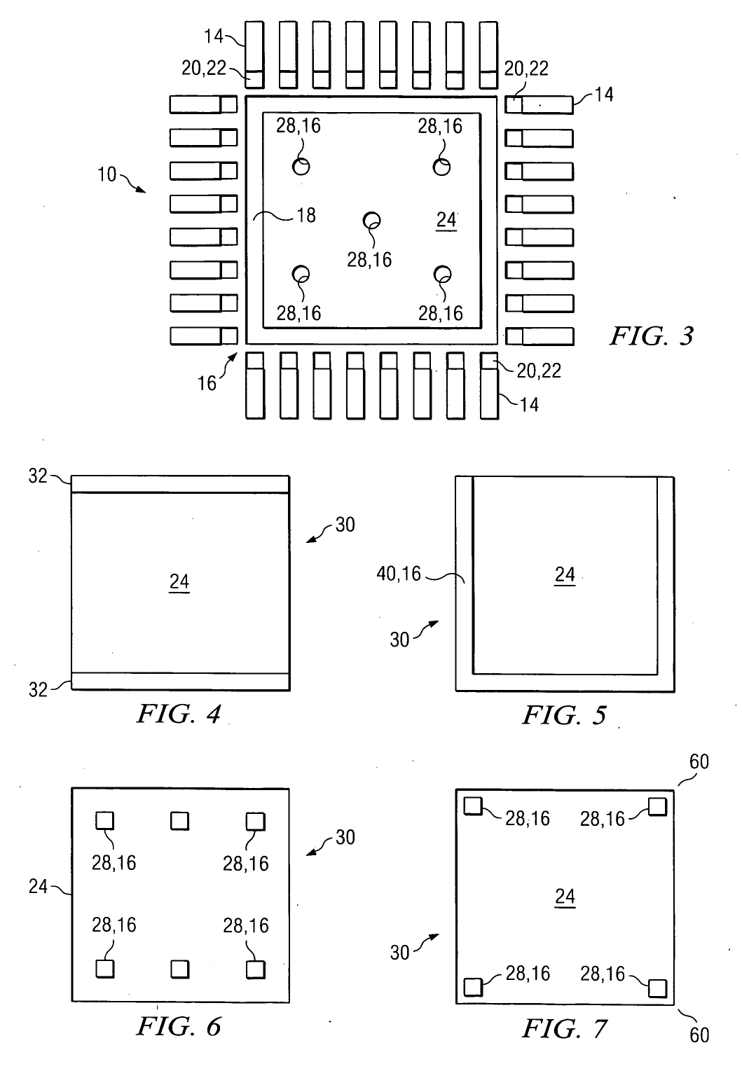

It should be understood by those skilled in the arts, and is demonstrated with further examples herein, that the location, geometry, and total area occupied by the coined portion 16 of the leadframe 10 is not limited to the configuration of the examples shown. It is contemplated that the coined portion 16 may be selected according to the application, and primarily according to the arrangement of electrical contact surfaces of a particular IC device for bonding to corresponding electrical contact points on a particular leadframe. Another example of a leadframe 10 according to a preferred embodiment of the invention is shown in FIG. 2. In this instance, a coined area 16 includes the periphery 18 of the die pad 12 as well as a region 20 of the leadfinger 14 tips 22. Additionally, internal locations 28 within the die pad 12 are coined 16. The size, internal locations 28, and geometry of the coining 16 shown and described herein is by way of example only, and in the practice of the invention may be selected according to the specifics of the application. It is believed that this and similar embodiments are particularly advantageous in applications in which it is desirable to ensure flattened die pads, as with relatively large IC/leadframe combinations. Another example of a leadframe 10 according to an alternative preferred embodiment of the invention is shown in FIG. 3 to illustrate that the invention is not limited to a particular lead configuration and may be practiced in applications having leads on one, two, three, four, or more sides, to match virtually any desired chip configuration.

It will be recognized by those reasonably skilled in the arts that the various embodiments of the invention may be practiced with common leadframes such as those made from copper, iron, and their alloys, and with plated or unplated leadframes. It should also be apparent that the geometries of the leadframe examples herein, and variations thereof, are equally applicable to the manufacture and use of corresponding coining dies, and vice versa. Further examples of the faces of coining dies embodying the invention are depicted in FIGS. 4 through 7. FIG. 4 portrays a die 30 for use with a coining press. The die face 30 has a contact area 32 for making coining contact with a portion of a suitably positioned die pad upon application of coining pressure by the press. The die face 30 also has a non-contact area 24 for ensuring that a portion of the die pad is preserved from coining. In this example, the contact areas 32 occupy opposing edges of the die 30. FIG. 5 illustrates an additional example of a die face 40 with another arrangement of a contact area 42 and a non-contact area 24 for selectively coining portions of a suitable die. A further example is shown in FIG. 6, wherein a die face 50 has internal contact areas 52 positioned away from the edges 54 of the die and surrounded by non-contact area 24. FIG. 7 depicts an additional embodiment of the invention in which a die face 60 has contact areas 62 at the corners and non-contact areas 24 elsewhere.

A great many variations and combinations of the leadframes and dies of the examples of the invention cited herein are possible without departure from the invention so long as selected coined and uncoined areas are provided. With an improved coining die, leadframe, and method, the wirebond areas of a leadframe may be selectively coined for secure wirebonding, and other areas of the leadframe can be left uncoined to facilitate a secure bond between the attachment material and the metal of the leadframe. Adhesion of encapsulant material to portions of the leadframe that remain exposed subsequent to chip attachment may be enhanced as well. For chips requiring downbonding to the die pad, coining of a selected portion of the die pad surface, for example the periphery of the die pad, is provided for secure chip-to-leadframe electrical connections, and the rougher uncoined leadframe die pad surface that remains provides for improved die attach adhesion.

The methods and apparatus of the invention provide advantages including but not limited to promoting electrical and mechanical bonding in assembled IC packages. While the invention has been described with reference to certain illustrative embodiments, those described herein are not intended to be construed in a limiting sense. Various modifications and combinations of the illustrative embodiments as well as other advantages and embodiments of the invention will be apparent to persons skilled in the arts upon reference to the drawings, description, and claims.

I claim:

1. A method of forming a leadframe comprising the steps of:
providing a leadframe including a die pad, and including leadfingers extending from the die pad; and
coining at least one selected portion of the die pad using a high pressure coining tool configured to make contact with the at least one selected portion of the die pad and further configured to avoid contact with the remainder of the die pad.

2. A method of forming a leadframe according to claim 1 wherein the selected portion of the die pad area comprises at least one edge of the die pad.

3. A method of forming a leadframe according to claim 1 wherein the selected portion of the die pad comprises at least one corner of the die pad.

4. A method of forming a leadframe according to claim 1 wherein the selected portion of the die pad comprises the periphery of the die pad.

5. A method of forming a leadframe according to claim 1 wherein the selected portion of the die pad comprises one or more internal areas of the die pad surface.

6. A leadframe comprising:
at least one coined leadframe portion providing at least one surface for bonding to an electrical contact; and
at least one uncoined leadframe portion providing an attachment surface for bonding to a semiconductor device.

7. A leadframe according to claim 6 wherein the at least one coined leadframe portion comprises a leadfinger.

8. A leadframe according to claim 6 wherein the at least one coined leadframe portion comprises a portion of a die pad.

9. A leadframe according to claim 6 wherein the at least one coined leadframe portion comprises at least one portion of one edge of a die pad.

10. A leadframe according to claim 6 wherein the at least one coined leadframe portion comprises at least one corner a die pad.

11. A leadframe according to claim 6 wherein the at least one coined leadframe portion comprises the periphery of a die pad.

12. A leadframe according to claim 6 wherein the at least one coined leadframe portion comprises at least one internal area of a die pad surface.

13. A leadframe coining tool for use in a high pressure press, the tool comprising:
at least one die portion for alignment with a leadframe having a die pad, the at least one die portion further comprising at least one contact area for coining a portion of the die pad, and at least one non-contact area for ensuring that at least one portion die pad remains uncoined;
whereby the die pad of the aligned leadframe may be partially coined and partially uncoined upon application of the tool by the high pressure press.

14. A leadframe coining tool according to claim 13 wherein at least one contact area for coining is disposed to coin at least one portion of one leadfinger of the leadframe.

15. A leadframe coining tool according to claim 13 wherein at least one contact area disposed to coin a portion of the die pad further comprises at least contact area portion disposed to coin at least one portion of one edge of the die pad.

16. A leadframe coining tool according to claim 13 wherein at least one contact area disposed to coin a portion of the die pad further comprises at least contact area portion disposed to coin at least one corner of the die pad.

17. A leadframe coining tool according to claim 13 wherein at least one contact area disposed to coin a portion of the die pad further comprises at least contact area portion disposed to coin the periphery of the die pad.

18. A leadframe coining tool according to claim 13 wherein at least one contact area disposed to coin a portion of the die pad further comprises at least one contact area portion disposed to coin at least one internal area of the die pad surface.
